(19) United States
(12) Patent Application Publication
(10) Pub. No.: US 2026/0042225 A1
(43) Pub. Date: Feb. 12, 2026

(54) SUBSTRATE TRANSFER DEVICE AND METHOD FOR DETERMINING ABNORMALITY OF SUBSTRATE TRANSFER DEVICE

(71) Applicant: EUGENE TECHNOLOGY CO., LTD., Yongin-si, Gyeonggi-do (KR)

(72) Inventors: Jun Jin HYON, Yongin-si, Gyeonggi-do (KR); Byoung Gyu SONG, Yongin-si, Gyeonggi-do (KR); Jung Ki MIN, Yongin-si, Gyeonggi-do (KR); Hyeong Sik KO, Yongin-si, Gyeonggi-do (KR); Hyeong Hwan BAE, Yongin-si, Gyeonggi-do (KR)

(21) Appl. No.: 18/852,434

(22) PCT Filed: Mar. 28, 2023
(86) PCT No.: PCT/KR2023/004109

§ 371 Date: Apr. 15, 2025

(30) Foreign Application Priority Data
Apr. 1, 2022 (KR) 10-2022-0041059

(51) Int. Cl. B25J 11/00; B25J 15/00; B25J 19/02; B25J 19/06; H01L 21/677

(52) U.S. Cl. CPC B25J 11/0095; B25J 15/0052; B25J 19/021; B25J 19/06; H01L 21/67766

(57) ABSTRACT

The present inventive concept relates to a substrate transfer device that detects an abnormality of a plurality of end-effectors and a method for determining an abnormality of the substrate transfer device. The substrate transfer device includes: a plurality of end-effectors extending in a first direction and disposed in multi-stages in a second direction crossing the first direction to support substrates, respectively; an interval adjustment unit configured to adjust an interval between the plurality of end-effectors; and an abnormality detection unit configured to detect an abnormality of each of the plurality of end-effectors, wherein the plurality of end-effectors may include: a reference end-effector that is fixed in position; and a variable end-effector that is adjusted in distance from the reference end-effector with respect to the reference end-effector.

### TECHNICAL FIELD

The present inventive concept relates to a substrate transfer device and a method for determining an abnormality in the substrate transfer device, and more particularly, to a substrate transfer device for detecting an abnormality in a plurality of end-effectors and a method for determining an abnormality in the substrate transfer device.

### BACKGROUND ART

In order to perform a unit process in a semiconductor manufacturing process, a plurality of devices that are suitable for each process characteristic are provided, and each of the different types of devices is provided with a substrate transfer device for transferring a substrate such as a wafer. In general, a substrate transfer device in a semiconductor facility serves to transfer a substrate from a load-lock chamber to a substrate accommodation member (e.g., FOUP, carrier, etc.) or from the substrate accommodation member to the load-lock chamber.

In a batch type substrate processing device, a plurality of substrates are loaded in multiple stages onto a substrate boat in the load-lock chamber, and then the substrate processing process is performed on the plurality of substrates. Here, in order to shorten a substrate transfer time (e.g., loading time), the substrate transfer device may have two or more end-effectors, and two or more substrates may be unloaded from the substrate accommodation member and then loaded onto a substrate boat at once.

The substrate transfer device may experience abnormalities such as sagging of the plurality of end-effector, and when an interval between the plurality of end-effectors is changed due to the abnormality of the plurality of end-effectors, damage such as scratches may occur while the substrate enters the substrate boat or the substrate accommodation member, or a major accident such as pushing and throwing down of the substrate boat may occur.

Thus, to solve these problems, a technology in which sagging of the end-effector is detected to determine abnormalities in interval between the plurality of end-effectors.
(Patent Document 1) Korean Patent Publication No. 10-2020-0130058

### DISCLOSURE OF THE INVENTIVE CONCEPT

### Technical Problem

The present inventive concept provides a substrate transfer device, which detects an abnormality of a plurality of end-effectors such as sagging of the end-effectors to prevent defective transfer of a substrate, and a method for determining an abnormality of the substrate transfer device.

### Technical Solution

A substrate transfer device according to an embodiment of the present inventive concept includes: a plurality of end-effectors extending in a first direction and disposed in multi-stages in a second direction crossing the first direction to support substrates, respectively; an interval adjustment unit configured to adjust an interval between the plurality of end-effectors; and an abnormality detection unit configured to detect an abnormality of each of the plurality of end-effectors, wherein the plurality of end-effectors may include: a reference end-effector that is fixed in position; and a variable end-effector that is adjusted in distance from the reference end-effector with respect to the reference end-effector.

The abnormality detection unit may include a light emitting part and a light receiving part, wherein the light emitting part may include a plurality of light sources provided in numbers corresponding to the number of plurality of end-effectors.

The plurality of light sources may be fixed at positions different from each other in the second direction.

The plurality of light sources may include: a first light source corresponding to the reference end-effector; and a second light source provided at a position different from that of the first light source in the second direction.

The second light source may be provided in plurality, and a distance between the first light source and the second light source, which are adjacent to each other, may be different from a distance between the second light sources that are adjacent to each other.

The distance between the first light source and the second light source, which are adjacent to each other, may be greater than or equal to a minimum interval between the plurality of end-effectors and be less than the distance between the second light sources that are adjacent to each other.

The abnormality detection unit may include: a light amount measurement part configured to measure an amount of light received by the light receiving part; and an abnormality determination part configured to determine an abnormality of each of the plurality of end-effectors through the measured light amount.

The abnormality detection unit may further include a determination criterion storage part configured to store the amount of light received by the light receiving part according to the interval between plurality of end-effectors.

The variable end-effector may be provided in plurality, and the plurality of variable end-effectors may be disposed symmetrically with respect to the reference end-effector.

A method for determining an abnormality of a substrate transfer device according to another embodiment of the present inventive concept includes: storing an amount of light received to a light receiving part of an abnormality detection unit from a light emitting part of the abnormality detection unit for each interval of a plurality of end-effectors, while adjusting the interval between the plurality of end-effectors including a reference end-effector and a variable end-effector; first measuring an amount of light received by the light receiving part in a state in which the interval between the plurality of end-effectors is set to a first interval; comparing the stored amount of light at the first interval with the amount of light measured in the first measuring; second measuring the amount of light received by the light receiving part in a state in which the interval between the plurality of end-effectors is set to a second interval different from the first interval; and comparing the stored amount of light at the second interval with the amount of light measured in the second measuring.

The stored amount of light at the second interval may be different from the stored amount of light at the first interval.

The second measuring may be performed when a difference between the stored amount of light at the first interval and the amount of light measured in the first measuring is within an allowable error range.

The method may further include additionally measuring the amount of light received by the light receiving part in a state in which the interval between the plurality of end-effectors is set to an interval other than the first interval and the second interval so as to be compared with the stored amount of light at the interval other than the first and second intervals.

The light emitting part may include a plurality of light sources provided in numbers corresponding to the number of plurality of end-effectors, and the first interval and the second interval may be determined depending on positions of the plurality of light sources.

The light irradiated from a first light source corresponding to the reference end-effector among the plurality of light sources may be at least partially blocked by the reference end-effector in a normal state.

The plurality of light sources may further include a second light source provided at a position different from that of the first light source, and one or less variable end-effectors may be disposed between the first light source and the second light source, which are adjacent to each other.

An interval between the plurality of end-effectors may be adjusted by driving a motor, and the method may further include storing motor encoder values of the first interval and the second interval.

The variable end-effector may be provided in plurality, and the plurality of variable end-effectors may be disposed symmetrically with respect to the reference end-effector.

### Advantageous Effects

The substrate transfer device according to the embodiment of the present inventive concept may detect the abnormality of the plurality of end-effectors through the abnormality detection unit to identify the abnormality of the end-effectors before transferring the substrate, thereby preventing the damage of the substrate and/or the throwing down of the substrate boat due to the defective transfer of the end-effectors from occurring in advance.

Here, the abnormality detection unit may include the light emitting part and the light receiving part, and the light emitting part may include the plurality of light sources provided in numbers corresponding to the plurality of end-effectors to effectively detect the sagging of each of the plurality of end-effectors.

In addition, the plurality of light sources may include the first light source corresponding to the reference end-effector and the second light source provided at the position different from that of the first light source (in the second direction), and the first light source and the second light source may be fixed at the positions different from each other (in the second direction). In this case, the first light source may irradiate the light (e.g., straight light) to the reference end-effector in the normal state and adjust the interval between the plurality of end-effectors through the interval adjustment unit, and thus, even when the interval between the plurality of end-effectors is adjusted through the interval adjustment unit, the abnormality of the plurality of end-effectors may be detected without moving (or adjusting) the positions of the plurality of light sources.

### BRIEF DESCRIPTION OF THE DRAWINGS

FIG. 1 is a schematic cross-sectional view of a substrate transfer device according to an embodiment of the present inventive concept.

FIG. 2 is a schematic cross-sectional view for explaining an abnormality detection unit according to an embodiment of the present inventive concept.

FIG. 3 is a conceptual view for explaining abnormality detection of a plurality of end-effectors according to an embodiment of the present inventive concept.

FIG. 4 is a flowchart illustrating a method for determining an abnormality of a substrate transfer device according to another embodiment of the present inventive concept.

### MODE FOR CARRYING OUT THE INVENTIVE CONCEPT

Hereinafter, specific embodiments will be described in more detail with reference to the accompanying drawings.

The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

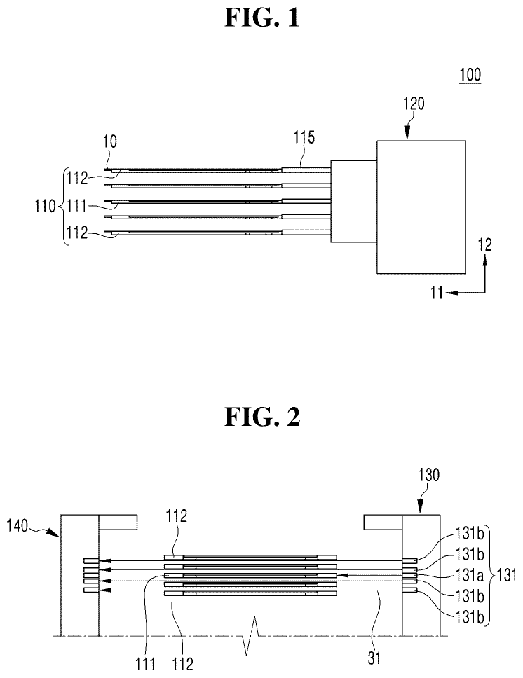

FIG. 1 is a schematic cross-sectional view of a substrate transfer device according to an embodiment of the present inventive concept, and FIG. 2 is a schematic cross-sectional view for explaining an abnormality detection unit according to an embodiment of the present inventive concept.

Referring to FIGS. 1 and 2, a substrate transfer device 100 according to an embodiment of the present inventive concept may include: a plurality of end-effectors 110 extending in a first direction 11 and disposed in multiple stages in a second direction 12 crossing the first direction 11 to support the substrate 10; an interval adjustment unit that adjusts an interval between the plurality of end-effectors 110; and abnormality detection units 130 and 140 that detect an abnormality of the plurality of end-effectors 110.

The plurality of end-effectors 110 may extend in the first direction 11 and be disposed (or stacked) in the second direction 12 crossing the first direction 11 to provide a multi-stage structure, and the substrate 10 may be supported on each stage (i.e., each of the plurality of end-effectors). That is, two or more substrates 10 corresponding to the number of end-effectors 110 may be transferred at once. Here, the first direction 11 may be a forward and backward direction or a left and right direction in a horizontal direction, and the second direction 12 may be orthogonal to the first direction 11 and may be a vertical direction (or upward/downward direction).

For example, the plurality of end-effectors 110 may have a fork shape including a plurality of fingers disposed (or arranged) in a third direction crossing both the first direction 11 and the second direction 12, which are parallel to each other in the first direction 11, and may be in contact with a bottom surface of the substrate 10 to support the substrate 10. Here, the third direction may be a direction crossing the first direction 11 of the horizontal directions and may be a left and right direction when the first direction 11 is the forward and backward direction and may be a forward and backward direction when the first direction 11 is the left and right direction. In addition, the plurality of end-effectors 110 may be made of a ceramic material such as quartz, aluminum oxide (Al₂O₃), aluminum nitride (AlN), silicon carbide (SiC), titanium dioxide (TiO₂), and silicon dioxide (SiO). Here, the substrate 10 may be a wafer, but is not particularly limited thereto, and may also be a glass substrate, etc.

The plurality of end-effectors 110 may be connected to each other in one direction 11 by an end-effector hand 115, and each of the plurality of end-effectors 110 may be fixed (or maintained) in a horizontal state. For example, the end-effector hand 115 may be made of a different material from that of each of the plurality of end-effectors 110 and may be made of a metal such as aluminum (Al), but is not particularly limited thereto. When each of the plurality end-effectors 110 and the end-effector hand 115 are made of different materials, cracks in the plurality of end-effectors 110 or loosening of a bolt connecting each of the plurality of end-effectors 110 to the end-effector hand 115 may occur to cause the sagging abnormality (or abnormal sagging) in the plurality of end-effectors 110.

The interval adjustment unit 120 may be connected to the plurality of end-effectors 110 to adjust the interval between the plurality of end-effectors 110. Here, the interval adjustment unit 120 may adjust the interval between the plurality of end-effectors 110 in the second direction 12. For example, the interval adjustment unit 120 may be connected to the end-effector hand 115 and then connected to the plurality of end-effectors 110, and the interval between the plurality of end-effectors 110 may be adjusted through the end-effector hand 115. Here, when there are three or more end-effectors 110, the interval(s) between two adjacent end-effectors 110 may be the same.

A loading interval of the substrate 10 on a substrate boat (not shown) may vary depending on a configuration (or structure) of the substrate boat (not shown) and/or a process of processing the substrate 10, and two or more substrates 10 may be stably loaded at the same time to correspond to various substrate boats (not shown) having different loading intervals of the substrate 10 through the interval adjustment unit 120.

In addition, a loading interval of the substrate 10 of a substrate accommodation member (not shown) such as a front opening unified pod (FOUP) or a carrier and a loading interval of the substrate 10 of the substrate boat (not shown) may be different from each other, and the interval between the plurality of end-effectors 110 may be adjusted to match the loading interval of the substrate 10 of the substrate accommodation member (not shown) through the interval adjustment unit 120 to unload two or more substrates from the substrate accommodation member (not shown) at the same time. In addition, the interval between the plurality of end-effectors may be adjusted to match the loading interval of the substrate 10 of the substrate boat (not shown) to unload two or more substrates 10 from the substrate accommodation member (not shown), thereby loading the substrates on the substrate boat (not shown) at the same time.

Conversely, the interval between the plurality of end-effectors 110 may be adjusted to match the loading interval of the substrate 10 of the substrate boat (not shown) through the interval adjustment unit 120, thereby removing two or more substrates 10 at a time from the substrate boat (not shown). In addition, the interval between the plurality of end-effectors 110 may be adjusted to match an accommodating interval of the substrate 10 of the substrate accommodation member (not shown), thereby accommodating the processed substrate 10 into the substrate accommodation member (not shown).

Thus, the interval between the plurality of end-effectors 110 may be adjusted through the interval adjustment unit 120 to correspond to various substrate boats (not shown) having loading intervals different from each other and also respond even when an accommodation interval of the substrate accommodation member (not shown) and the loading interval of the substrate 10 of the substrate boat (not shown) are different from each other.

The abnormality detection units 130 and 140 may detect an abnormality of the plurality of end-effectors 110 such as sagging of plurality of end-effectors 110. For example, the abnormality detection units 130 and 140 may detect the sagging of the plurality of end-effectors 110 and confirm (or identify) the abnormality of the plurality of end-effectors 110, such as poor transfer.

If the end-effector 110 is inclined due to the sagging, the substrate 10 may slip, or when the substrate 10 is loaded onto the substrate boat (not shown), the substrate 10 may collide with a protrusion (e.g., a partition plate, substrate support tip, etc.) protruding from an inner surface of the substrate boat (not shown) when the substrate 10 is loaded on the substrate boat (not shown) to cause scratches, thereby damaging the substrate 10. In addition, in the worst case scenario, the sagging (or inclined) end-effector 110 may push the substrate boat (not shown) to throw down, resulting in a major accident.

However, the substrate transfer device 100 of the present inventive concept may detect the abnormality such as the sagging of the plurality of end-effectors 110 before transferring the substrate through the abnormality 10 detection units 130 and 140. Thus, the abnormality of the plurality of end-effectors 110 may be identified to prevent the damage of the substrate 10 and/or the throwing down of the substrate boat (not shown) in advance.

Here, the plurality of end-effectors 110 may include: a reference end-effector 111 of which a position is fixed; and a variable end-effector 112 of which a distance from the reference end-effector 111 is adjusted with respect to the reference end-effector 111. The reference end-effector 111 may be fixed in position, and the position in the second direction 12 may be fixed. That is, the reference end-effector 111 may not move in the second direction 12, and the variable end-effector 112 may move in the second direction 12 with respect to the fixed reference end-effector 111 to change the interval between the plurality of end-effectors 110.

The variable end-effector 112 may be adjusted in distance from the reference end-effector 111 with respect to the reference end-effector 111, and the variable end-effector 112 may move in the second direction 12 with respect to the reference end-effector 111 to change a distance between the reference end-effector 111 and the variable end-effector 112, thereby adjusting the interval between the plurality of end-effectors.

The substrate transfer device 100 according to the present inventive concept may detect the abnormality of the plurality of end-effectors 110 such as the sagging of the plurality of end-effectors 110 through abnormality detection units 130 and 140 to identify the abnormality of the plurality of end-effectors 110 before transferring the substrate 10, thereby preventing the damage of the substrate 10 and/or the throwing down of the substrate boat (not shown) due to the poor transfer of the plurality of end-effectors 110 in advance.

Here, the abnormality detection units 130 and 140 may include a light emitting part 130 and a light receiving part 140. The light emitting part 130 and the light receiving part 140 may be disposed to face each other and may be disposed in the third direction crossing the first direction 11 in which the end-effector and when detecting the abnormality of the plurality of end-effectors 110, at least one end-effector 110 may be disposed between the light emitting part 130 and the light receiving part 140.

For example, when the light emitting part 130 irradiates light (e.g., straight light) toward the light receiving part 140, the sagging of the plurality of end-effectors 110 may be determined based on a light receiving state (or whether light is received) of the light 31 at the light receiving part 140. In general, the light emitting part 130 and the light receiving part 140 may be disposed at the same height (or the same position in the second direction) to transmit and receive horizontal light (i.e., the straight light). Here, the light 31 may be straight light or may be a thru-beam such as a laser beam or an infrared ray (IR).

That is, the abnormality detection units 130 and 140 may detect the sagging of the plurality of end-effectors 110 in an optical sensing manner through the light emitting part 130 and the light receiving part 140. For example, in a normal state, the light 31 may be received by the light receiving part 140, but the light 31 may be covered by the end-effector 110 in which the sagging occurs, and thus, the sagging of the end-effector 110 may be detected in a constant non-detection manner for the end-effector 110 into which the light is not received by the light receiving part 140. Conversely, in the normal state, the light 31 may be covered by the end-effector 110 being detected by the light 31 and may not be received by the light receiving part 140, but when the end-effector 110 sags, the light 31 may be received by the light receiving part 140, and thus, the sagging of the end-effector 110 may be detected in a constant detection manner for the end-effector 110.

Thus, in the present inventive concept, the sagging of the end-effector 110 may be detected in the optical sensing manner through the light emitting part 130 and the light receiving part 140 to effectively detect the abnormality of the plurality of end-effectors 110.

In addition, the light emitting part 130 may include a plurality of light sources 131 provided in a number corresponding to the plurality of end-effectors 110. The plurality of light sources 131 may be provided in numbers corresponding to the plurality of end-effectors 110, be provided in the same number as the plurality of end-effectors 110, and be provided to one-to-one correspond to the plurality of end-effectors 110, but is not particularly limited thereto.

For example, at least one light source 131 may be provided to correspond to each of the plurality of end-effectors 110. Here, the light source 131 may be provided to correspond to each of the plurality of end-effectors 110, one light source 131 may be provided to correspond to the reference end-effector 111, and one or more (for example, two) light sources 131 may be provided to correspond to the variable end-effector 112. Here, the largest number of light sources 131 may be provided to correspond to the variable end-effector 112 that is furthest from the reference end-effector 111.

In addition, the plurality of light sources 131 may emit (or irradiate) the light 31, irradiate the straight light, and be optical fibers, lasers, etc. Here, the light receiving part 140 may have the number (e.g., the same number) of light receiving surfaces corresponding to the plurality of light sources 131 and may receive the light(s) 31 irradiated from the plurality of light sources 131 on one light receiving surface. In order to effectively detect the sagging of each of the plurality of end-effectors 110, it may be desirable for the light receiving part 140 to have a light receiving surface corresponding to the plurality of light sources 131, but it is not particularly limited thereto.

Here, the abnormality detection units 130 and 140 may detect the sagging of the end-effector 110 in the above-described constant non-detection manner using the plurality of light sources 131 to determine the abnormality in interval between the plurality of end-effectors 110. In addition, the abnormality detection units 130 and 140 may detect the sagging of the end-effector 110 in the above-described constant n t detection manner using the plurality of light sources 131 to determine the abnormality in interval between the plurality of end-effectors 110.

Thus, the sagging of each of the plurality of end-effectors 110 may be detected to determine the abnormality in interval between the plurality of end-effectors 110, thereby preventing the damage of the substrate 10 and/or the throwing down of the substrate boat (not shown) due to the poor interval between the plurality of end-effectors 110 from occurring, and thus, two or more substrates 10 may be stably loaded on the substrate boat (not shown) in which the loading interval of the substrate 10 is fixed. That is, the light emitting part 130 may include the plurality of light sources 131 provided in numbers corresponding to the plurality of end-effectors 10 to effectively detect the sagging (or abnormality) for each of the plurality of end-effectors 10, thereby preventing the damage of the substrate 10 and/or the throwing down of the substrate boat (not shown) due to the poor interval between the plurality of end-effectors 110 from occurring.

Here, the plurality of light sources 131 may be fixed at different positions in the second direction 12. In general, when adjusting the interval between the plurality of end-effectors 110 through the interval adjustment unit 120, the positions of the plurality of light sources 131 may be adjusted according to the interval between plurality of end-effectors 110 to detect the sagging of each of the plurality of end-effectors 110 corresponding to each of the plurality of light sources 131. In this case, a separate configuration such as a position adjustment unit for adjusting the positions of the plurality of light sources 131 is required.

However, in the present inventive concept, even when the interval between the plurality of end-effectors 110 is adjusted through the interval adjustment unit 120, the position of each of the plurality of light sources 131 in the second direction 12 may be appropriately determined to effectively detect the sagging of the plurality of end-effectors 110 without adjusting the positions of the plurality of light sources 131 in a state in which the plurality of light sources 131 are fixed in different positions in the second direction 12, and also detect the sagging of each of the plurality of end-effectors 110. Thus, the separate configuration such as the position adjustment unit may not be required, and the sagging of each of the plurality of end-effectors 110 may be effectively detected without the separate configuration such as the position adjustment unit. Here, the position of each of the plurality of light sources 131 in the second direction 12 may be appropriately determined according to the number of end-effectors 110, and (all) the interval(s) between two adjacent light sources 131 may be the same, or at least one of the intervals between the two adjacent light sources 131 may be different.

For example, the plurality of light sources 131 may include: a first light source 131a corresponding to the reference end-effector 111; and a second light source 131b provided at a different position from the first light source 131a in the second direction 12. The first light source 131a may be provided to correspond to the reference end-effector 111 to detect sagging (or abnormality) of the reference end-effector 111. Here, the first light source 131a may be fixed at the same position (height) in the second direction 12 as the reference end-effector 111, and the light 31 irradiated from the first light source 131a may be at least partially blocked (or covered) by the reference end-effector 111 in the normal state. Here, the position of the first light source 131a in the first direction 11 and/or the position of the first light source 131a in the third direction may be different from that of the reference end-effector 111.

The second light source 131b may be provided (or fixed) at a position different from that of the first light source 131a in the second direction 12, may have a position (or height) different from that of the first light source 131a in the second direction 12, and may detect abnormality (or sagging) of the variable end-effector 112.

Here, the light 31 irradiated from the second light source 131b may pass above (or through an upper side) or below (or through a lower side) the variable end-effector 112 depending on the change in position (or movement) of the variable end-effector 112 and then be received by the light receiving part 140 or may be at least partially blocked (or covered) by the variable end-effector 112.

For example, the light 31 irradiated from the second light source 131b disposed adjacent to an upper (or lower) portion of the first light source 131a may pass through an upper (or lower) portion of the variable end-effector 112 disposed adjacent to an upper (or lower) portion of the reference end-effector 111 at a minimum interval between the plurality of end-effectors 110 (or a minimum interval between the reference end-effector and the variable end-effector adjacent to each other). In addition, the light 31 irradiated from the second light source 131b disposed adjacent to an upper (or lower) portion of the first light source 131a may pass through the upper (or lower) portion of the variable end-effector 112 disposed adjacent to the lower (or upper) portion of the reference end-effector 111 at a maximum interval between the plurality of end-effectors 110 (or a maximum interval between the reference end-effector and the variable end-effector adjacent to each other). In addition, the light 31 irradiated from the second light source 131b disposed adjacent to an upper (or lower) portion of the first light source 131a may be blocked (or covered) by the variable end-effector 112 disposed adjacent to an upper (or lower) portion of the reference end-effector 111 at a minimum interval between the plurality of end-effectors 110 (or an intermediate interval between the minimum interval and the maximum interval between the reference end-effector and the variable end-effector adjacent to each other).

Here, the minimum interval between the plurality of end-effectors 110 may be a minimum interval that is capable of being adjusted by the interval adjustment unit 120 and may be an interval between the plurality of end-effectors 110 when the end-effector hands 115 are in contact with each other to overlap each other. The minimum interval between the plurality of end-effectors 110 may be larger than a thickness of the substrate 10 so that the plurality of substrates 10 are supported (in multiple stages) between the plurality of end-effectors 110. In addition, the maximum interval between the plurality of end-effectors 110 may be a maximum interval that is capable of being adjusted by the interval adjustment unit 120. For example, the maximum interval between the plurality of end-effectors 110 may be smaller than a height of the substrate accommodation member (not shown) and/or the substrate boat (not shown) and may be an interval at which the adjacent reference end-effector 111 and the variable end-effector 112 are the farthest apart from each other without blocking the light 31 irradiated from the second light source 131b to which each variable end-effector 112 does not correspond (or does non-correspond) to each other.

Here, the second light source 131b may be configured in plurality, and two or more second light sources 131b may be provided to effectively detect the sagging (or abnormality) of the variable end-effector 112, and in the case in which there are a plurality of variable end-effectors 112, the plurality of variable end-effectors 112 may be provided to correspond to (or according to) the number of variable end-effectors 112. Through this, the sagging (or abnormality) of the variable end-effector 112 corresponding to each second light source 131b may be effectively detected. That is, the sagging (or abnormality) of each corresponding variable end-effector 112 may be detected through (the plurality of) second light sources 131b provided corresponding to respective variable end-effectors 112, and the sagging (or abnormality) of the plurality of end-effectors 110 may be effectively detected together with the reference end-effector 111 through the first light source 131a. Here, at least one second light source 131b may be provided corresponding to each variable end-effector 112, and the number of second light sources 131b provided corresponding to respective variable end-effectors 112 may vary depending on the variable end-effector 112 (for example, depending on the position of the variable end-effector).

In addition, a distance between the first light source 131a and the second light source 131b which are adjacent to each other may be different from a distance between the second light source 131b and the second light source 131b. In the case in which the plurality of light sources 131 are arranged at equal intervals (i.e., the distance between the first light source and the second light source, which are adjacent to each other, and the distance between the second light sources adjacent to each other are the same), the interval of the plurality of end-effectors 110 has to always be adjusted to a constant interval (or predetermined interval) corresponding to the interval of the plurality of light sources 131 (for example, equal to the interval of the plurality of light sources), and then the abnormality of the plurality of end-effectors 110 has to be detected.

However, after the interval of the plurality of end-effectors 110 is adjusted to be different from the predetermined interval by the interval adjustment unit 120, it is difficult to accurately (or precisely) match the interval of the plurality of end-effectors 110 to the predetermined interval, and whenever the interval of the plurality of end-effectors 110 is matched to the predetermined interval, a slight (or minute) error may occur in the predetermined interval.

When measuring an amount of light received by the light receiving part 140 at an interval at which an error occurs from the above-mentioned regular interval, there may be a difference from the amount of light received by the light receiving part 140 measured at the above-mentioned regular interval. As a result, it becomes difficult to determine whether the plurality of end-effectors 110 are abnormal, such as determining that the plurality of end-effectors 110 are abnormal even when no sagging of the end-effector 110 occurs, and the accuracy of for precision) the abnormality determination may be deteriorated. In addition, due to the interval error from the above-mentioned predetermined interval, slight sagging of the end-effector 110 (e.g., sagging less than the interval error from the above-mentioned predetermined interval) may not be detected.

Thus, the distance between the first light source 131a and the second light source 131b which are adjacent to each other may be different from the distance between the second light source 131b and the second light source 131b. In this case, it is possible to determine the abnormality of the plurality of end-effectors 110 at two or more (or multiple) intervals, and thus, even slight sagging of the end-effector 110 may be detected to determine the abnormality of the plurality of end-effectors 110, and the accuracy of determining the abnormality of the plurality of end-effectors 110 may be improved.

For example, in the normal state (or ordinary times), only the light 31 irradiated from the first light source 131a may be covered by the reference end-effector 111 at an interval (e.g., the minimum interval or the maximum interval between the plurality of end-effectors), and then, an amount of light received by the light receiving part 140 may be (primarily) measured, and an amount of light received by the light receiving part 140 at at least one or more other intervals may be (secondarily) measured by increasing or decreasing the interval between the plurality of end-effectors 110. Here, not only the light 31 irradiated from the first light source 131a but also the light 31 irradiated from at least one second light source 131b may be measured at least in the amount of light received by the light receiving part 140 at the interval covered by the variable end-effector 112, and the interval between the plurality of end-effectors 110 may increase or decrease so that the light 31 irradiated from the corresponding second light source 131b is allowed to pass through (or via) (each of) the variable end-effectors 112. Here, a point in time at which each variable end-effector 112 covers the light 31 irradiated from the corresponding second light source 131b may vary (i.e., the interval between the plurality of end-effectors) depending on the distance (in the second direction) from the reference end-effector 111.

Here, in the case of the normal state, the amount of light received by the light receiving part 140 may be measured at multiple intervals at which all variable end-effectors 112 block the light 31 irradiated from the corresponding second light source 131b at least once. As a results, when determining the abnormality of the plurality of end-effectors 110, it is also possible to know which end-effector 110 among the plurality of end-effectors 110 has sagging (or abnormality).

That is, in the present inventive concept, while the interval between plurality of end-effectors 110 increases or decreases at (from) the interval at which only the light 31 irradiated from the first light source 131a is covered by the reference end-effector 111 in the normal state, the amount of light received by the light receiving part 140 may be measured multiple times (or at the multiple intervals), and thus, not only there be no difficulty in accurately matching the above-described constant interval, but also the accuracy of the abnormality determination of the plurality of end-effectors 110 may be improved, and even the slight sagging of the end-effector 110 may be detected.

The distance between the first light sources 131a and the second light sources 131b, which are adjacent to each other, may be greater than or equal to the minimum interval between the plurality of end-effectors 110 and may be less than the distance between the second light sources 131b adjacent to each other. When the distance between the first light source 131a and the second light source 131b, which are adjacent to each other, is smaller than the minimum interval between the plurality of end-effectors 110, the interval between the plurality of end-effectors 110 in the normal state may be adjusted so that the variable end-effector 112 adjacent to the reference end-effector 111 covers the light irradiated from the second light source 131b adjacent to the first light source 131a. That is, when the distance between the first light source 131a and the second light source 131b, which are adjacent to each other, is smaller than the minimum interval between the plurality of end-effectors 110, the variable end-effector 112 adjacent to the reference end-effector 111 may not pass through the light irradiated from the second light source 131b adjacent to the first light source 131a, and thus, the accurate (or precise) detection of the abnormality (or sagging detection) of the variable end-effector 112 adjacent to the reference end-effector 111 may not be performed.

For example, the second light source 131b adjacent to the first light source 131a at a distance that is smaller than the minimum interval of the plurality of end-effectors 110 may detect the abnormality of the variable end-effector 112 adjacent to the reference end-effector 111 only when the variable end-effector 112 adjacent to the reference end-effector 111 is sagging under specific conditions (e.g., inclination). That is, the second light source 131b adjacent to the first light source 131a at a distance smaller than the minimum interval of the plurality of end-effectors 110 may detect the sagging (or abnormality) of the reference end-effector 111 by overlapping the role of the first light source 131a or may not detect the abnormality (or sagging) of the variable end-effector 112 adjacent to the lower portion of the reference end-effector 111.

In addition, when the distance between the adjacent first light sources 131a and second light sources 131b is greater than the distance between the second light sources 131b, which are adjacent to each other, even if the interval between the plurality of end-effectors 110 in the normal state is adjusted within a range of the minimum interval to the maximum interval, the variable end-effector 112 adjacent to the reference end-effector 111 may not block the light irradiated from the second light source 131b adjacent to the first light source 131a, or the light irradiated from at least one second light source 131b such as the second light source 131b adjacent to the first light source 131a may be covered by two or more variable end-effectors 112 respectively by adjusting the interval between the plurality of end-effectors 110. In this case, it becomes impossible to accurately detect the abnormality (or sagging) of the plurality of end-effectors 110 such as the variable end-effectors 112 adjacent to the reference end-effector 111.

For example, if the variable end-effector 112 adjacent to the reference end-effector 111 do not block the light irradiated from the second light source 131b adjacent to the first light source 131a, the abnormality (or sagging) may not be detected for the variable end-effector 112 adjacent to the reference end-effector 111. In addition, when the light irradiated from the at least one second light source 131b is covered by two or more variable end-effectors 112, it becomes difficult to determine that the variable end-effector 112 has the abnormality (or sagging), and it becomes difficult to determine that the light irradiated from the at least one second light source 131b is covered by the variable end-effector 112 in the normal state or by the variable end-effector 112 in which the abnormality (or sagging) occurs.

Thus, the distance between the first light source 131a and the second light source 131b, which are adjacent to each other, may be larger than the minimum interval between the plurality of end-effectors 110 and smaller than the distance between the second light source 131b adjacent to each other, it is possible to accurately detect (or determine) the abnormality (or sagging) of each of the plurality of end-effectors 110. Here, the variable end-effector 112 adjacent to the reference end-effector 111 may pass through the light irradiated from the second light source 131b adjacent to the first light source 131a from the lower side to the upper side (or from the upper side to the lower side), and thus, the burden (or difficulty) of having to precisely match the interval between the plurality of end-effectors 110 to the predetermined interval may be eliminated. As a result, it may be preferable that the distance between the first light source 131a and the second light source 131b, which are adjacent to each other, is greater than the minimum interval between the plurality of end-effectors 110.

That is, in the substrate transfer device 100 according to the present inventive concept, the plurality of the light sources 131 including the first light source 131a corresponding to the reference end-effector 111 and the second light source 131b provided at a position different from that of the first light source 131a in the second direction 12 so as to be fixed at different positions in the second direction 12, and thus, the first light source 131a may irradiate the light to the reference end-effector 111 in the normal state, and the variable end-effector 112 may pass through the light 31 irradiated from the second light source 131b according to the interval adjustment of the plurality of end-effectors 110 through the interval adjustment unit 120. Thus, even when the interval of the plurality of end-effectors 110 is adjusted through the interval adjustment unit 120, the abnormality of the plurality of end-effectors 110 may be detected without moving (or adjusting) the positions of the plurality of light sources 131.

The abnormality detection units 130 and 140 may further include: a light amount measurement part (not shown) that measures an amount of light received by the light receiving part 140; and an abnormality determination part (not shown) that determines the abnormality of the plurality of end-effectors 110 based on the measured light amount. The light amount measurement part (not shown) may measure the amount of light received by the light receiving part 140, measure the amount of light 31 irradiated from each light source 131 individually, or measure the total amount of light 31 irradiated from the plurality of light sources 131. The amount of light 31 irradiated from each light source 131 may vary depending on the distance from the first light source 131a based on the first light source 131a. Thus, it is possible to clearly determine that the light 31 irradiated from which light source 131 is covered, and also, the amount of light 31 irradiated from the second light source 131b disposed farthest from the first light source 131a of which the light 31 is almost (always) received by the light receiving part 140 may be to (relatively) reduced, or the amount of light 31 from the first light source 131a of which the light 31 is (always) covered by the reference end-effector 111 may be to (relatively) reduced before the abnormality (or sagging) occurs in the reference end-effector 111 to reduce power consumption due to the light emission of the plurality of light sources 131.

For example, the light measurement part (not shown) may determine not only whether the light 31 is received by the light receiving part 140 through an on/off switch, but also how much (or how much) of the light 31 is covered by the end-effector 110 due to the sagging of the end-effector 110. The light amount measurement part (not shown) may also determine how many end-effectors 110 have the abnormality based on the total amount of light received by the light receiving part 140 when the light 31 is irradiated from the plurality of light sources 131.

The abnormality determination part (not shown) may determine the abnormality of the plurality of end-effectors 110 based on the light amount measured by the light amount measurement part (not shown), determine the sagging of each of the plurality of end-effectors 110, and determine the abnormality in interval between the plurality of end-effectors 110. Here, if the amount of light measured by the above light amount measurement part (not shown) may have a difference by a predetermined amount or more from that in the ordinary day (or the normal state), it may be determined that the end-effector 110 is sagging, and it may be determined that the interval between the plurality of end-effectors 110 is abnormal.

For example, when the light amount measured by the light amount measurement part (not shown) have a difference by 100% from that in the ordinary day (i.e., when the light received by the light receiving part is turned on/off), it may be determined that the interval between the plurality of end-effectors 110 is abnormal (or the end-effector is sagging), and when the light amount measured by the light amount measurement part (not shown) has a difference by 50% from that in the ordinary day, it may be determined that the interval between the plurality of end-effectors 110 is abnormal (or the end-effector is sagging). Here, the above-mentioned predetermined amount may be determined as an appropriate amount that is capable of accurately determining the sagging of the end-effector 110 (or the interval between the plurality of end-effectors).

In general, when the sagging of the end-effector 110 occurs (or the interval between the plurality of end-effectors exceeds the interval), the end-effector 110 may completely cover or escape the light 31 irradiated from the light source 131, and the end-effector 110 may sag slightly more or less than the position of the light 31 irradiated from the light source 131 (or the position of the straight light) due to the slight error depending on the situation. When the end-effector 110 is slightly more or less sagging than the position of the light 31 irradiated from the light source 131, a portion of the total amount of light 31 irradiated from the light source 131 may be received by the light receiving part 140. In this case, if the sagging of the end-effector 110 (or the interval between the plurality of end-effectors) is determined only by the on/off of the light 31 irradiated from the light source 131 (or the on/off of the light received by the light receiving part), when a slight error occurs depending on the situation, it may not be determined as the sagging of the end-effector 110 (or the interval between the plurality of end-effectors).

Conversely, if even the slight change in the amount of light measured by the above-described light amount measurement part (not shown) is determined as the sagging of the end-effector 110 (or an amount greater than the interval between the plurality of end-effectors), the slight change in amount of light may occur even with slight sagging due to a load of the end-effector 110 or slight shaking due to movement of the end-effector 110, and thus, even the thing that is not the sagging of the end-effector 110 (or an amount greater than the interval between the plurality of end-effectors) is determined as the sagging of the end-effector 110 (or an amount greater than the interval between the plurality of end-effectors). Thus, when the amount of light measured by the light amount measurement part (not shown) is changed by more than 50% (i.e., 50% of the amount of light irradiated from the light source), it may be desirable to determine that the end-effector 110 is sagging (or the interval between the plurality of end-effectors is abnormal), but this is not particularly limited thereto.

In addition, even if there is the slight sagging in the end-effector 110, there are cases in which the substrate 10 is transferred depending on the loading interval of the substrate 10 of the substrate boat (not shown) and/or the accommodation interval of the substrate 10 of the substrate accommodation member (not shown). For example, in the case in which the loading interval of the substrate 10 of the substrate boat (not shown) and/or the accommodation interval of the substrate 10 of the substrate accommodation member (not shown) is wide, there is no difficulty in loading or accommodating the substrate 10 even if there is the slight sagging in the end-effector 110, and thus, the substrate 10 may be loaded or accommodated. However, if the loading interval of the substrate 10 of the substrate boat (not shown) and/or the accommodation interval of the substrate 10 of the substrate accommodation member (not shown) is narrow, even small sagging in the end-effector 110 may easily cause the damage of the substrate 10 such as scratches. Thus, even the small sagging in the end-effector 110 needs to be determined as being greater than the interval between a plurality of end-effectors 110.

Thus, the above-mentioned predetermined amount may be determined according to the loading interval of the substrate 10 of the substrate boat (not shown) and/or the accommodation interval of the substrate 10 of the substrate accommodation member (not shown). For example, in proportion to the loading interval of the substrate 10 of the substrate boat (not shown) and/or the accommodation interval of the substrate 10 of the substrate accommodation member (not shown), the narrower the loading interval of the substrate 10 of the substrate boat (not shown) and/or the accommodation interval of the substrate 10 of the substrate accommodation member (not shown), the loading interval of the smaller the substrate 10 of the substrate boat (not shown) and/or the accommodation interval of the substrate 10 of the substrate accommodation member (not shown), the loading interval of the larger the substrate 10 of the substrate boat (not shown) and/or the accommodation interval of the substrate 10 of the substrate accommodation member (not shown).

Thus, the abnormality detection units 130 and 140 may measure the amount of light received by the light receiving part 140 through the light amount measurement part (not shown) to determine the abnormality of the plurality of end-effectors 110 (for example, the sagging of the end-effector or the abnormality in interval between the plurality of end-effectors), thereby accurately determining whether the substrate 10 is transferred according to the loading interval of the substrate 10 of the substrate boat (not shown) and/or the accommodation interval of the substrate 10 of the substrate accommodation member (not shown).

Maintenance of the end-effector 110 may also be determined based on the amount of light measured by the above-mentioned light measurement part (not shown). The sagging of the end-effector 110 may be caused by breakage of the end-effector 110 made of a ceramic material or loosening of a bolt connecting the end-effector 110 to the end-effector hand 115, and the inclination (or angle) of the sagging may vary depending on the cause of the sagging. Thus, the cause of the sagging may be identified by a difference in amount of light received by the light receiving part 140 due to the difference in the inclination of the sagging. If the breakage occurs in the end-effector 110, the end-effector 110 has to be replaced, but if only the bolt is loosed, only the bolt needs to be tightened, and thus, the transfer of the substrate 10 may be temporarily stopped to perform the maintenance of the end-effector 110. In addition, when the sagging occurs due to the loosening of the bolt, the sagging gradually may occur depending on a degree of the loosening of the bolt, and thus, the maintenance of the end-effector 110 may be determined after the inclination of the sagging has sagged to a predetermined inclination (or a predetermined angle) or more, and the inclination of the sagging may be obtained through calculation using the amount of light measured by the light amount measurement part (not shown).

The abnormality detection units 130 and 140 may further include a determination criterion storage part (not shown) that store the amount of light received by the light receiving part 140 according to the interval between plurality of end-effectors 110. The determination criterion storage part (not shown) may store the amount of light received by the light receiving part 140 according to the interval between plurality of end-effectors 110. Here, the amount of light received by the light receiving part 140 may be measured for each interval of the plurality of end-effectors 110 while changing the interval between the plurality of end-effectors 110 in advance, and the amount of light received by the light receiving part 140 according to the interval between the plurality of end-effectors 110 may be stored in the determination criterion storage part (not shown), or the amount of light received by the light receiving part 140 according to the intervals between the plurality of end-effectors 110 may be stored (or updated) in the determination criterion storage part (not shown) whenever the amount of light received by the light receiving part 140 at each interval between the plurality of end-effectors 110 is measured.

When the amount of light received by the light receiving part 140 at each interval between the plurality of end-effectors 110 is stored in the determination criterion storage part (not shown), the abnormality determination part (not shown) may compare the amount of light measured (now) by the light amount measurement part (not shown) with the amount of light received by the light receiving part 140 at each measurement interval between the plurality of end-effectors 110, which is stored in the determination criterion storage part (not shown). Here, if there is a difference between the measured light amount and the light amount received by the light receiving part 140 at the measurement interval, it may be determined that there is the abnormality in the plurality of end-effectors 110, and if the difference between the measured light amount and the light amount received by the light receiving part 140 at the measurement interval is out of an allowable error range, it may also be determined that there is the abnormality in the plurality of end-effectors 110. Here, the amount of light may be measured at multiple (or two or more) (measurement) intervals, and the measured amount of light at each interval may be compared with the amount of light stored in the determination criterion storage part (not shown) (i.e., the amount of light received by the light receiving part), and the abnormality in the plurality of end-effectors 110 may be determined at each interval.

The variable end-effector 112 may be provided in plurality. Thus, three or more substrates 10 may be transferred at once, and transfer efficiency of the substrates 10 may be further improved. As the number of variable end-effectors 112 increases, the arrangement of the plurality of variable end-effectors 112 may become important.

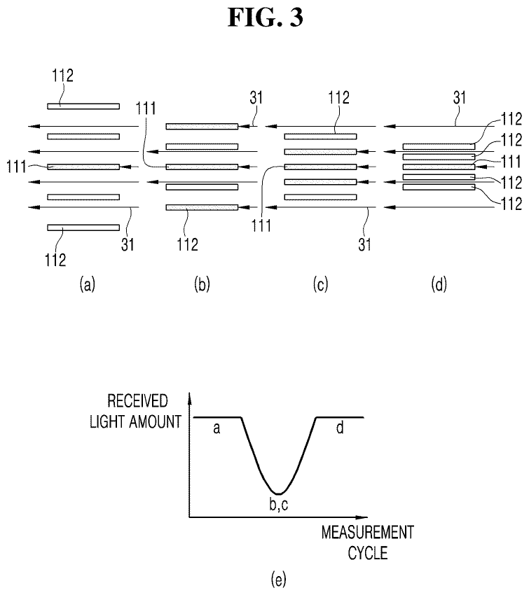

FIG. 3 is a conceptual view for explaining abnormality detection of the plurality of end-effectors according to an embodiment of the present inventive concept. (a) of FIG. 3 illustrate light amount measurement of an initial interval (or a maximum interval) of the plurality of end-effectors, (b) of FIG. 3 illustrates light amount measurement of a second interval of the plurality of end-effectors, (c) of FIG. 3 illustrates light amount measurement of a third interval of the plurality of end-effectors, and (d) of FIG. 3 illustrates light amount measurement of a critical interval (or a minimum interval) of the plurality of end-effectors. In addition, (e) of FIG. 3 is a graph illustrating an amount of light received at the light receiving part for each light amount measurement cycle.

Referring to FIG. 3, the plurality of variable end-effectors 112 may be symmetrical with respect to the reference end-effector 111 and may be disposed (or arranged) symmetrically at both sides (or the upper and lower portions) of the reference end-effector 111 in the second direction 12. In the case in which the plurality of variable end-effectors 112 are disposed symmetrically around the reference end-effector 111, a pair of variable end-effectors 112 at the same distance from the reference end-effector 111 may be generated, and thus, in the case of the normal state, the number of above-described plurality of intervals at which all variable end-effectors 112 cover the light 31 irradiated from the corresponding second light source 131b at least once may be reduced and also may be reduced to half (i.e., half the number) of the plurality of variable end-effectors 112. That is, the number of plurality of intervals for measuring the amount of light received by the light receiving part 140 may be minimized.

For example, as illustrated in FIG. 3, it may be provided as five end-effectors 110 with two variable end-effectors 112 which are disposed above and below the standard end-effector 111 with respect to the standard end-effector 111, respectively, and the amount of light received by the light receiving part 140 may be measured at four intervals. As illustrated in (a) of FIG. 3, only the light 31 irradiated from the first light source 131a may be covered by the reference end-effector 111 in the normal state may be covered at the maximum interval (or initial interval) of the plurality of end-effectors 110, and the amount of light received by the light receiving part 140 at the maximum interval (e.g., the first interval) of the plurality of end-effectors 110 may be measured first. Here, the light 31 irradiated from the second light source(s) 131b above the first light source 131a may pass through the lower portion of each variable end-effector 112 above the reference end-effector 111 and be received by the light receiving part 140.

In addition, the light 31 irradiated from the second light source(s) 131b below the first light source 131a may pass through the upper portion of each variable end-effector 112 below the reference end-effector 111 and be received by the light receiving part 140.

In addition, as in (b) of FIG. 3, while reducing the interval between plurality of end-effectors 110, the amount of light received by the light receiving part 140 may be secondly measured at the second interval at which the light 31 irradiated from the outermost second light source(s) 131b in the normal state is also covered by the pair of variable end-effectors 112 that are farthest (or outermost) from the reference end-effector 111. Here, the light 31 irradiated from the second light source 131b adjacent to the upper portion of the first light source 131a may pass through the lower portion of the variable end-effector 112 adjacent to the upper portion of the reference end-effector 111 and be received by the light receiving part 140. In addition, the light 31 irradiated from a second light source 131b adjacent to the lower portion of the first light source 131a may pass through the upper portion of the variable end-effector 112 adjacent to the lower portion of the reference end-effector 111 and be received by a light receiving part 140.

In addition, as in (c) of FIG. 3, while (further) reducing the interval between the plurality of end-effectors 110, the amount of light received by the light receiving part 140 may be thirdly measured at the third interval at which the light 31 irradiated from the second light source(s) 131b adjacent to the first light source 131a in the normal state is also covered by the pair of variable end-effectors 112 adjacent to the reference end-effector 111. Here, the light 31 irradiated from the first light source 131a may be covered by the reference end-effector 111. In addition, the light 31 irradiated from the second light source 131b at the outermost side above the first light source 131a may pass through the upper portion of the upper outermost variable end-effector 112 and be received by the light receiving part 140. In addition, the light 31 irradiated from the outermost second light source 131b below the first light source 131a may pass through the lower part of the outermost variable end-effector 112 and be received by the light receiving part 140.

In addition, as in (d) of FIG. 3, the interval between the plurality of end-effectors 110 may be reduced to the minimum interval (or critical interval) between the plurality of end-effectors 110, only the light 31 irradiated from the first light source 131a may be covered by the reference end-effector 111 in the normal state at the minimum interval between the plurality of end-effectors 110, and the amount of light received by the light receiving part 140 may be fourthly measured at the minimum interval (for example, fourth interval) between the plurality of end-effectors 110. Here, the light 31 irradiated from the second light source(s) 131b above the first light source 131a may pass through the upper portion of each variable end-effector 112 above the reference end-effector 111 and be received by the light receiving part 140. In addition, the light 31 irradiated from the second light source(s) 131b below the first light source 131a may pass through the lower portion of each variable end-effector 112 below the reference end-effector 111 and be received by the light receiving part 140.

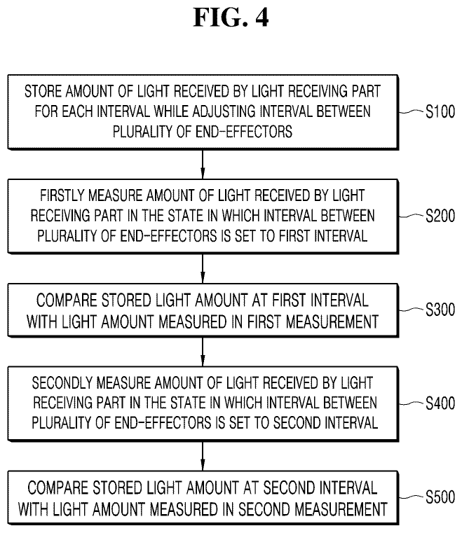

FIG. 4 is a flowchart illustrating a method for determining an abnormality of a substrate transfer device according to another embodiment of the present inventive concept.

Referring to FIG. 4, a method for determining an abnormality of a substrate transfer device according to another embodiment of the present inventive concept will be examined in more detail. However, details that overlap those described above in relation to the substrate transfer device according to an embodiment of the present inventive concept will be omitted.

A method for determining an abnormality of a substrate transfer device according to another embodiment of the present inventive concept may include: a process (S100) of storing an amount of light received to a light receiving part of an abnormality detection unit from a light emitting part of the abnormality detection unit for each interval of a plurality of end-effectors, while adjusting the interval between the plurality of end-effectors including a reference end-effector and a variable end-effector; a process (S200) of first measuring an amount of light received by the light receiving part in a state in which the interval between the plurality of end-effectors is set to a first interval; a process (S300) of comparing the stored amount of light at the first interval with the amount of light measured in the process (S200) of the first measuring; a process (S400) of second measuring the amount of light received by the light receiving part in a state in which the interval between the plurality of end-effectors is set to a second interval different from the first interval; and a process (S500) of comparing the stored amount of light at the second interval with the amount of light measured in the process (S400) of the second measuring.

First, while adjusting the interval between the plurality of end-effectors including the reference end-effector and the variable end-effector, the amount of light received from the light emitting part of the abnormality detection unit to the light receiving part of the abnormality detection unit is stored for each interval between the plurality of end-effectors (S100). While adjusting the interval of the plurality of end-effectors including the reference end-effector and the variable end-effector by using an interval adjustment unit capable of adjusting the interval of the plurality of end-effectors, the amount of light received by the light receiving part of the abnormality detection unit from the light emitting part of the abnormality detection unit may be stored in a determination criterion storage part for each interval between the plurality of end-effectors. As described above, the amount of light received by the light receiving part stored in the determination criterion storage part at each interval of the plurality of end-effectors may be used to detect (or determine) the abnormality in the plurality of end-effectors.

Here, the plurality of end-effectors may extend in a first direction and include the reference end-effector and the variable end-effector, and the interval between the end-effectors may be adjusted in a second direction crossing the first direction by the interval adjustment unit. The reference end-effector may be fixed in position, and the position in the second direction may be fixed. That is, the reference end-effector may not move (or be elevated) in the second direction, and the variable end-effector may move in the second direction with respect to the fixed reference end-effector to change the interval between the plurality of end-effectors.

The variable end-effector may be adjusted in distance from the reference end-effector with respect to the reference end-effector, and the variable end-effector may move in the second direction with respect to the reference end-effector to change the distance between the reference end-effector and the variable end-effector, and thus, the interval between the plurality of end-effectors may be adjusted.

The determination criterion storage part may store the amount of light received by the light receiving part according to the interval between the plurality of end-effectors. Here, the amount of light received by the light receiving part may be measured at each interval of the plurality of end-effectors while changing the intervals of the plurality of end-effectors in advance, and the amount of light received by the light receiving part may be stored in the determination criterion storage part according to the intervals of the plurality of end-effectors, or the amount of light received by the light receiving part may be stored (or updated) according to the intervals of the plurality of end-effectors whenever the amount of light received by the light receiving part is measured at each interval of the plurality of end-effectors. Here, the amount of light received by the light receiving part according to the interval between the plurality of end-effectors in the normal state may be stored in the determination criterion storage part.

Next, the amount of light received by the light receiving part is firstly measured in the state in which the interval between the plurality of end-effectors is set to the first interval (S200). With the interval between the plurality of end-effectors set to the first interval, the amount of light received by the light receiving part may be firstly measured by the light amount measurement part of the abnormality detection unit, and the first measured amount of light may be used to be compared with the amount of light received by the light receiving part at the first interval stored in the determination criterion storage part. For example, the interval between the plurality of end-effectors may be adjusted to the first interval through the interval adjustment unit to (first) measure the amount of light received by the light receiving part at the first interval. The above-mentioned light amount measurement part may measure the amount of light received by the light receiving part and may also measure the amount of light radiated from each light source of the light emitting part or measure the total amount of light radiated from a plurality of light sources.

For example, the light measurement part may determine not only whether light is received by the light receiving part (on/off), but also how much (or how much) light is covered by the end-effector due to sagging of the end-effector. The light amount measurement part may also determine how many end-effectors have an abnormality based on the total amount of light received by the light receiving part when light is irradiated from a plurality of light sources.

In addition, the stored amount of light at the first interval may be compared with the amount of light measured in the process (S200) of the first measuring (S300). The amount of light at the first interval stored in the determination criterion storage part and the amount of light measured in the process (S200) of the first measuring may be compared with each other in the abnormality determination part of the abnormality detection unit. For example, if there is a difference between the stored amount of light received by the light receiving part at the first interval and the amount of light measured in the process (S200) of the first measuring, it may be determined that there is the abnormality in the plurality of end-effectors. In addition, if the difference between the stored amount of light received by the light receiving part at the first interval and the amount of light measured in the process (S200) of the first measuring is out of an allowable error range, it may be determined that there is the abnormality in the plurality of end-effectors. The abnormality determination part may determine the abnormality of the plurality of end-effectors based on the light amount measured by the light amount measurement part, determine the sagging of each of the plurality of end-effectors, and determine the abnormality in interval between the plurality of end-effectors. Here, if the amount of light measured by the above light amount measurement part may have a difference, which is out of the allowable error range, by a predetermined amount or more from that in the ordinary day (or the normal state), it may be determined that the end-effector is sagging, and it may be determined that the interval between the plurality of end-effectors is abnormal.

For example, when the light amount measured by the light amount measurement part have a difference by 100% from that in the ordinary day (i.e., when the light received by the light receiving part is turned on/off), it may be determined that the interval between the plurality of end-effectors is abnormal (or the end-effector is sagging), and when the light amount measured by the light amount measurement part has a difference by 50% from that in the ordinary day, it may be determined that the interval between the plurality of end-effectors is abnormal (or the end-effector is sagging). Here, the above-mentioned predetermined amount may be determined as an appropriate amount that is capable of accurately determining the sagging of the end-effector (or the interval between the plurality of end-effectors).

In general, when the sagging of the end-effector occurs (or the interval between the plurality of end-effectors exceeds the interval), the end-effector may completely cover or escape the light irradiated from the light source, and the end-effector may sag slightly more or less than the position of the light irradiated from the light source (or the position of the straight light) due to the slight error depending on the situation. When the end-effector is slightly more or less sagging than the position of the light irradiated from the light source, a portion of the total amount of light irradiated from the light source may be received by the light receiving part. In this case, if the sagging of the end-effector (or the interval between the plurality of end-effectors) is determined only by the on/off of the light irradiated from the light source (or the on/off of the light received by the light receiving part), when a slight error occurs depending on the situation, it may not be determined as the sagging of the end-effector (or the interval between the plurality of end-effectors).

Conversely, if even the slight change in the amount of light measured by the above-described light amount measurement part is determined as the sagging of the end-effector (or an amount greater than the interval between the plurality of end-effectors), the slight change in amount of light may occur even with slight sagging due to a load of the end-effector or slight shaking due to movement of the end-effector, and thus, even the thing that is not the sagging of the end-effector (or an amount greater than the interval between the plurality of end-effectors) is determined as the sagging of the end-effector (or an amount greater than the interval between the plurality of end-effectors). Thus, when the amount of light measured by the light amount measurement part is changed by more than 50% (i.e., 50% of the amount of light irradiated from the light source), it may be desirable to determine that the end-effector is sagging (or the distance between the plurality of end-effectors is abnormal), but this is not particularly limited thereto.

Next, the amount of light received by the light receiving part is secondly measured in the state in which the interval between the plurality of end-effectors is set to a second interval different from the first interval (S400). The amount of light received by the light receiving part is secondly measured while the interval between the plurality of end-effectors is set to a second interval different from the first interval. Here, the interval between the plurality of end-effectors may be adjusted to the second interval through the interval adjustment unit to (second) measure the amount of light received by the light receiving part at the second interval, and the second measured amount of light may be used to be compared with the amount of light received by the light receiving part at the second interval stored in the determination criterion storage part. Here, the second interval may be different from the first interval.

In addition, the stored amount of light at the second interval may be compared with the amount of light measured in the process (S400) of the second measuring (S500). The amount of light at the second interval stored in the determination criteria storage part may be compared with the amount of light measured in the process (S400) of the second measuring. For example, if there is a difference between the stored amount of light received by the light receiving part at the second interval and the amount of light measured in the process (S400) of the second measuring, it may be determined that there is the abnormality in the plurality of end-effectors. In addition, if the difference between the stored amount of light received by the light receiving part at the second interval and the amount of light measured in the process (S400) of the second measuring is out of the allowable error range, it may be determined that there is the abnormality in the plurality of end-effectors.

As described above, the abnormality determination part may compare the light amount measured (now) by the light amount measurement part with the light amount received by the light receiving part at the measurement intervals (e.g., the first interval and the second interval) of the plurality of end-effectors stored in the determination criterion storage part. Here, the abnormality determination part may determine that there is the abnormality in the plurality of end-effectors when there is a difference between the measured light amount and the light amount received by the light receiving part at the measurement interval. Here, the abnormality determination part may determine that there is the abnormality in the plurality of end-effectors when a difference in measured light amount and the light amount received by the light receiving part at the measurement interval is out of the allowable error range. Here, the amount of light may be measured at least in the first interval and the second interval (i.e., two or more (measurement intervals) to compare the measured amount of light at each interval with the amount of light stored in the determination criterion accommodation part (not shown) (i.e., the amount of light received by the light receiving part), and the abnormality in the plurality of end-effectors may be determined at each interval.

The process (S100) of storing the amount of light received by the light receiving part at each interval of the plurality of end-effectors, the process (S200) of the first measuring, the process (S300) of comparing the amount of light measured in the process (S200) of the first measuring; the process (S400) of the second measuring; and the process (S500) of comparing the amount of light measured in the process (S400) of the second measuring may be performed before supporting the substrate on the plurality of end-effectors to perform (or start) substrate transfer (process) (in a state in which the plurality of end-effectors do not support the substrate). As a result, the method for determining the abnormality of the substrate transfer device according to the present inventive concept may determine an abnormality of the substrate transfer device, such as an abnormality of the plurality of end-effectors to start (or perform) the substrate transfer (process) only when there is no abnormality of the plurality of end-effectors.

Here, the amount of light in the stored second interval may be different from the stored amount of light at the first interval. That is, the number (or amount) of light sources irradiating light that is covered by the plurality of end-effectors in the normal state at the first interval and the second interval may be different from each other.

In other words, since it is impossible to determine (or detect) the abnormality of the plurality of end-effectors at the plurality (or more than two) intervals when (all) the intervals of the plurality of light sources are the same, at least one of the intervals of the plurality of light sources may be different from the other interval(s). In such a case, the number (or amount) of the end-effectors that cover the light irradiated from each light source at different first and second intervals may be different from each other, and the stored amount of light at the first interval may be different from the stored amount of light at the second interval.

When the stored amount of light at the second interval is different from the stored amount of light at the first interval, the intervals of the plurality of end-effectors may be identified by the amount of light at each interval, and the abnormality of the plurality of end-effectors may be effectively determined at each interval, and also, whether the end-effector has the abnormality such as sagging may be determined.

The process (S400) of the second measuring may be performed when the difference between the stored amount of light at the first interval and the amount of light measured in the process (S200) of the first measuring is within the allowable error range. The process (S400) of the second measuring may be performed (only) when the difference between the stored amount of light at the first interval and the amount of light measured in the process (S200) of the first measuring is within the allowable error range. That is, if the difference between the stored amount of light at the first interval and the amount of light measured in the process (S200) of the first measuring exceeds the allowable error range, it means that the abnormality such as the sagging already occurs in the plurality of end-effectors, and thus, the substrate transfer device such as the plurality of end-effectors may be maintained without performing the process (S400) of the second measuring.

If at least one interval among the plurality of light sources is different from the other interval(s), only the sagging (or abnormality) of some of the plurality of end-effectors may be detected (or determined) at the first interval, and thus, if the difference between the stored amount of light at the first interval and the amount of light measured in the process (S200) of the first measuring is within the allowable error range, the process (S400) of the second measuring may be performed to detect the sagging for the remaining end-effectors for which the abnormality such as the sagging is not detected (or determined) at the first interval, and the amount of light received by the light receiving part at the second interval may be (secondly) measured.

Even if the difference between the stored amount of light at the first interval and the amount of light measured in the process (S200) of the first measuring is within the allowable error range, the process (S400) of the second measuring may be performed to detect the sagging for the remaining end-effectors to determine that the end-effector has the abnormality such as the sagging.

The method for determining the abnormality of the substrate transfer device according to the present inventive concept may further include a process (S600) of additionally measuring the amount of light received by the light receiving part in a state in which the interval between the plurality of end-effectors is set to an interval other than the first interval and the second interval so as to be compared with the stored amount of light at an interval other than the first and second intervals.

Additionally, in the state in which the interval between the plurality of end-effectors is set to an interval other than the first interval and the second interval, the amount of light received by the light receiving part may be measured and compared with the stored amount of light at the interval other than the first and second intervals (S600). If the first measurement and the second measurement do not detect the abnormality (or sagging) for all of the plurality of end-effectors, the amount of light received by the light receiving part at intervals other than the first interval and the second interval may be additionally measured, and the measured amount of light may be compared with the stored amount of light at intervals other than the first and second intervals in the determination criterion storage part. Here, the process (S600) of comparing the amount of light at intervals other than the above-described intervals may be repeated (performed) until the abnormality is detected for all of the plurality of end-effectors, and also, the process (S200) of the first measuring, the process (S400) of the second measuring, and the process of comparing the amount of light at intervals other than the above (previous) intervals may be repeated at different intervals in which the amount of light received by the light receiving part is not measured. That is, in order to detect the abnormality for all of the plurality of end-effectors, the amount of light received by the light receiving part is measured at the first interval, the second interval, . . . , n-th interval (e.g., the third interval, the fourth interval, etc.), and the measured amount of light may be compared with the stored amount of light at each interval in the determination criterion storage part to determine the abnormality in the plurality of end-effectors.

The light emitting part may include a plurality of light sources provided in numbers corresponding to the plurality of end-effectors. The plurality of light sources may be provided in numbers corresponding to the plurality of end-effectors, be provided in the same number as the plurality of end-effectors, and be provided to one-to-one correspond to the plurality of end-effectors, but is not particularly limited thereto.

For example, at least one light source may be provided corresponding to each of the plurality of end-effectors, one light source may be provided corresponding to each of the plurality of end-effectors, one light source may be provided corresponding to the reference end-effector, and one or more (e.g., two) light sources may be provided corresponding to the variable end-effectors. Here, the largest number of light sources may be provided corresponding to the variable end-effector that is furthest from the reference end-effector.

In addition, the plurality of light sources may emit (or irradiate) light, e.g., irradiate straight light, and may be optical fibers, lasers, etc. Here, the light receiving part may have the number (e.g., the same number) of light receiving surfaces corresponding to the plurality of light sources and may receive the light(s) irradiated from the plurality of light sources on one light receiving surface. In order to effectively detect the sagging of each of the plurality of end-effectors, it may be desirable for the light receiving part to have a light receiving surface corresponding to the plurality of light sources, but it is not particularly limited thereto.

Here, the abnormality detection unit may detect the sagging of the end-effector in a non-detection manner using the plurality of light sources to determine an abnormality in interval between the plurality of end-effectors. In addition, the abnormality detection unit may detect the sagging of the end-effector in a detection manner using the plurality of light sources to determine an abnormality in interval between the plurality of end-effectors.

Thus, the sagging of each of the plurality of end-effectors may be detected to determine the abnormality in interval between the plurality of end-effectors, thereby preventing the damage of the substrate and/or the throwing down of the substrate boat (not shown) due to the poor interval between the plurality of end-effectors from occurring, and thus, two or more substrates may be stably loaded on the substrate boat (not shown) in which the loading interval of the substrate is fixed. That is, the light emitting part may include the plurality of light sources provided in numbers corresponding to the plurality of end-effectors to effectively detect the sagging (or abnormality) for each of the plurality of end-effectors, thereby preventing the damage of the substrate and/or the throwing down of the substrate boat (not shown) due to the poor interval between the plurality of end-effectors from occurring.

Here, the first interval and the second interval may be determined according to the positions of the plurality of light sources. The first interval and the second interval may be determined so that the number of end-effectors that cover the light irradiated from each of the plurality of light sources may be changed at the first interval and the second interval depending on the positions of the plurality of light sources. Thus, it is possible to detect (or determine) the abnormality (or the sagging) of the plurality of end-effectors at two or more (or plurality of) intervals.

The light irradiated from a first light source corresponding to the reference end-effector among the plurality of light sources may be at least partially blocked by the reference end-effector in a normal state. The first light source of the plurality of light sources may be provided corresponding to the reference end-effector and be fixed at the same position (or height) as the reference end-effector in the second direction, and the light irradiated from the first light source may be at least partially blocked (or covered) by the reference end-effector in the normal state. Thus, the sagging (or abnormality) of the reference end-effector may be detected through the first light source, and when the sagging occurs in the reference end-effector, and the amount of light received by the light receiving part is changed (for example, when the amount of light received by the light receiving part increases), it may be determined that the reference end-effector is abnormal (or sagging).

The plurality of light sources may further include a second light source provided at a different position from the first light source. The second light source may be provided (or fixed) at a position different from that of the first light source in the second direction, may have a position (or height) different from that of the first light source in the second direction, and may detect abnormality (or sagging) of the variable end-effector.

Here, the light irradiated from the second light source may pass above (or through an upper side) or below (or through a lower side) the variable end-effector depending on the change in position (or movement) of the variable end-effector and then be received by the light receiving part or may be at least partially blocked (or covered) by the variable end-effector.

For example, the light irradiated from the second light source disposed adjacent to an upper (or lower) portion of the first light source may pass through an upper (or lower) portion of the variable end-effector disposed adjacent to an upper (or lower) portion of the reference end-effector at a minimum interval between the plurality of end-effectors (or a minimum interval between the reference end-effector and the variable end-effector adjacent to each other). In addition, the light irradiated from the second light source disposed adjacent to an upper (or lower) portion of the first light source may pass through the upper (or lower) portion of the variable end-effector disposed adjacent to the lower (or upper) portion of the reference end-effector at a maximum distance between the plurality of end-effectors (or a maximum distance between the reference end-effector and the variable end-effector adjacent to each other). In addition, the light irradiated from the second light source disposed adjacent to an upper (or lower) portion of the first light source may be blocked (or covered) by the variable end-effector disposed adjacent to an upper (or lower) portion of the reference end-effector at a minimum distance between the plurality of end-effectors (or an intermediate distance between the minimum distance and the maximum distance between the reference end-effector and the variable end-effector adjacent to each other).

Here, the second light source may be configured in plurality, and two or more second light sources may be provided to effectively detect the sagging (or abnormality) of the variable end-effector, and in the case in which there are a plurality of variable end-effectors, the plurality of variable end-effectors may be provided to correspond to (or according to) the number of variable end-effectors. As a result, the sagging (or abnormality) of the variable end-effector corresponding to each of the second light sources may be effectively detected. That is, the sagging (or abnormality) of each corresponding variable end-effector may be detected through (the plurality of) second light sources provided corresponding to respective variable end-effectors, and the sagging (or abnormality) of the plurality of end-effectors may be effectively detected together with the reference end-effector through the first light source. Here, at least one second light source may be provided corresponding to each variable end-effector, and the number of second light sources provided corresponding to respective variable end-effectors may vary depending on the variable end-effector (for example, depending on the position of the variable end-effector).

In addition, one or less variable end-effectors may be disposed between the first light source and the second light source, which are adjacent to each other. In this case, (only) one variable end-effector corresponding to the second light source adjacent to the first light source may be detected. As a result, the interval between the plurality of end-effectors may be adjusted so that the variable end-effector adjacent to the reference end-effector passes through the light irradiated from the second light source adjacent to the first light source from a lower portion to an upper portion (or from an upper portion to a lower portion), the burden (or difficulty) of having to accurately adjust the interval between the plurality of end-effectors to a constant interval (or predetermined interval) may be eliminated, and the abnormality (or sagging) of each of the plurality of end-effectors may be accurately detected (or determined).

For example, the distance between the first light source and the second light source, which are adjacent to each other, may be different from the distance between the second light source and the second light source, which are adjacent to each other. In the case in which the plurality of light sources are arranged at equal distances (i.e., the distance between the first light source and the second light source, which are adjacent to each other, and the distance between the second light sources adjacent to each other are the same), the interval of the plurality of end-effectors has to always be adjusted to a constant interval (or predetermined interval) corresponding to the interval of the plurality of light sources (for example, equal to the interval of the plurality of light sources), and then the abnormality of the plurality of end-effectors has to be detected.

However, after the interval of the plurality of end-effectors is adjusted to be different from the predetermined interval by the interval adjustment unit, it is difficult to accurately (or precisely) match the interval of the plurality of end-effectors to the predetermined interval, and whenever the interval of the plurality of end-effectors is matched to the predetermined interval, a slight (or minute) error may occur in the predetermined interval.

When measuring an amount of light received by the light receiving part at an interval at which an error occurs from the above-mentioned regular interval, there may be a difference from the amount of light received by the light receiving part measured at the above-mentioned regular interval. As a result, it becomes difficult to determine whether the plurality of end-effectors are abnormal, such as determining that the plurality of end-effectors are abnormal even when no sagging of the end-effector occurs, and the accuracy (or precision) of the abnormality determination may be deteriorated. In addition, due to the interval error from the above-mentioned predetermined interval, slight sagging of the end-effector (e.g., sagging less than the interval error from the above-mentioned predetermined interval) may not be detected.

Thus, the distance between the first light source and the second light source, which are adjacent to each other, may be different from the distance between the second light source and the second light source, which are adjacent to each other. In this case, the abnormality of the plurality of end-effectors may be determined at two or more intervals, and thus, even slight sagging of the end-effector may be detected to determine the abnormality of the plurality of end-effectors, and the accuracy of determining the abnormality of the plurality of end-effectors may be improved.

Here, in the normal state (or ordinary times), only the light irradiated from the first light source may be covered by the reference end-effector at an interval (e.g., the minimum interval or the maximum interval between the plurality of end-effectors), and then, an amount of light received by the light receiving part may be (primarily) measured, and an amount of light received by the light receiving part at at least one or more intervals may be (secondarily) measured while increasing or decreasing the interval between the plurality of end-effectors. Here, not only the light irradiated from the first light source but also the light irradiated from at least one of the second light sources may be measured at least in amount of light received by the light receiving part at an interval covered by the variable end-effector, and the interval between the plurality of end-effectors may increase or decrease so that (each) variable end-effector passes through the light irradiated from the corresponding second light source. Here, a point in time at which each variable end-effector covers the light irradiated from the corresponding second light source may vary (i.e., the interval between the plurality of end-effectors) depending on the distance (in the second direction) from the reference end-effector.

Here, in the case of the normal state, the amount of light received by the light receiving part may be measured at multiple intervals at which all variable end-effectors may cover the light irradiated from the corresponding second light source at least once. As a results, when determining the abnormality of the plurality of end-effectors, it is also possible to know which end-effector among the plurality of end-effectors has sagging (or abnormality).

That is, in the present inventive concept, while the interval between plurality of end-effectors increases or decreases at (from) the interval at which only the light irradiated from the first light source is covered by the reference end-effector in the normal state, the amount of light received by the light receiving part may be measured multiple times (or at the multiple intervals), and thus, not only there be no difficulty in accurately matching the above-described constant interval, but also the accuracy of the abnormality determination of the plurality of end-effectors may be improved, and even the slight sagging of the end-effector may be detected.

In addition, the distance between the first light source and the second light source, which are adjacent to each other, may be greater than or equal to a minimum interval between the plurality of end-effectors and may be less than the distance between the second light source and the second light source, which are adjacent to each other. When the distance between the first light source and the second light source, which are adjacent to each other, is smaller than the minimum interval between the plurality of end-effectors, the interval between the plurality of end-effectors may be adjusted in the normal state so that the variable end-effector adjacent to the reference end-effector does not cover the light irradiated from the second light source adjacent to the first light source. The distance between the plurality of end-effectors, the variable end-effector adjacent to the reference end-effector may not pass through the light irradiated from the second light source adjacent to the first light source, and thus, the accurate (or precise) detection of the abnormality (or sagging detection) of the variable end-effector adjacent to the reference end-effector may not be performed.

That is, the second light source adjacent to the first light source at a distance smaller than the minimum interval of the plurality of end-effectors may detect the abnormality of the variable end-effector adjacent to the reference end-effector only when the variable end-effector adjacent to the reference end-effector is sagging under a specific condition (e.g., inclined). That is, the second light source adjacent to the first light source at a distance smaller than the minimum distance of the plurality of end-effectors may detect the sagging (or abnormality) of the reference end-effector by overlapping the role of the first light source or may not detect the abnormality (or sagging) of the variable end-effector adjacent to the lower portion of the reference end-effector.

In addition, when the distance between the adjacent first light sources and second light sources is greater than the distance between the second light sources, which are adjacent to each other, even if the distance between the plurality of end-effectors in the normal state is adjusted within a range of the minimum distance to the maximum distance, the variable end-effector adjacent to the reference end-effector may not cover the light irradiated from the second light source adjacent to the first light source, or the light irradiated from at least one second light source such as the second light source adjacent to the first light source may be covered by two or more variable end-effectors respectively by adjusting the distance between the plurality of end-effectors. In this case, it becomes impossible to accurately detect the abnormality (or sagging) of the plurality of end-effectors such as the variable end-effectors adjacent to the reference end-effector.

As described above, if the variable end-effector adjacent to the reference end-effector do not block the light irradiated from the second light source adjacent to the first light source, the abnormality (or sagging) may not be detected for the variable end-effector adjacent to the reference end-effector. In addition, when the light irradiated from the at least one second light source is covered by two or more variable end-effectors, it becomes difficult to determine that the variable end-effector has the abnormality (or sagging), and it becomes difficult to determine that the light irradiated from the at least one second light source is covered by the variable end-effector in the normal state or by the variable end-effector in which the abnormality (or sagging) occurs.

Thus, the distance between the first light source and the second light source, which are adjacent to each other, may be larger than the minimum interval between the plurality of end-effectors and smaller than the distance between the second light source adjacent to each other, it is possible to accurately detect (or determine) the abnormality (or sagging) of each of the plurality of end-effectors.

The amount of light irradiated from each of the plurality of light sources may vary depending on the distance from the first light source to the first light source. Thus, it is possible to clearly determine whether the light sources is covered, and the amount of light irradiated from the second light source disposed furthest from the first light source, of which light (or irradiated light) is almost (always) received by the light-receiving part may be (relatively) reduced, or the amount of light from the first light source, of which light (or irradiated light) is (always) covered by the reference end-effector before the abnormality (or sagging) occurs in the reference end-effector, thereby reducing power consumption due to the light emission from the plurality of light sources.

Here, the interval between the plurality of end-effectors may be controlled by driving a motor. For example, the interval between the plurality of end-effectors may be controlled by driving the motor, and a encoder value of the motor may vary (or be changed) depending on the interval between the plurality of end-effectors. In the process (S100) of storing the amount of light received by the light receiving part according to the intervals between the plurality of end-effectors by using the above-described process, the amount of light received by the light receiving part may be stored according to the encoder value of the motor according to the intervals between the plurality of end-effectors in the determination criterion storage part while adjusting the intervals between the plurality of end-effectors.

Here, the method for determining the abnormality of the substrate transfer device according to the present inventive concept may further include a process (S150) of storing the motor encoder values of the first interval and the second interval.

The motor encoder values at the first interval and the second interval may be stored (or recorded) (S150). The motor encoder values at the first interval and the second interval may be stored in the determination criterion storage part. Thus, the motor encoder values stored in the determination criterion storage part may be used to accurately (or precisely) and quickly adjust (or regulate) the intervals of the plurality of end-effectors to the first interval and/or the second interval, and an interval adjustment time for the plurality of end-effectors may be shortened, and detection determination may be made easily. For example, the motor may be driven to match (or adjust) the encoder value of the motor with the motor encoder value of the first interval, and the interval of the plurality of end-effectors may be adjusted (or regulated) to the first interval. In addition, the motor may be driven to match the encoder value of the motor with the motor encoder value of the second interval, and the interval of the plurality of end-effectors may be adjusted to the first interval. It is also possible to store (or record) the motor encoder values at intervals other than the above intervals (for example, the n-th interval such as the third interval, the fourth interval, etc.), and the motor encoder values at the intervals other than the above intervals may be used to accurately and quickly adjust the intervals of the plurality of end-effectors to the intervals other than the above intervals.

As described above, the motor encoder values at the first interval, the second interval, and/or other intervals at which at least one of the end-effectors covers the light irradiated from each of the light sources may be recorded to eliminate the need to precisely mount the plurality of light sources at each set (or determined) position and to shorten the adjustment time and facilitate the detection determination.

Here, the process (S150) of storing the motor encoder value may be performed before the process (S200) of the first measuring and the process (S400) of the second measuring.

The variable end-effector may be configured in plurality. Thus, three or more substrates may be transferred at once, and transfer efficiency of the substrates may be further improved. As the number of the variable end-effectors increases, an arrangement of the plurality of variable end-effectors may become important.

In addition, the plurality of variable end-effectors may be symmetrical with respect to the reference end-effector and may be disposed (or arranged) symmetrically at both sides (or upper and lower portions) of the second direction of the reference end-effector. When the plurality of the variable end-effectors are disposed symmetrically with respect to the reference end-effector, a pair of the variable end-effectors at the same distance from the reference end-effector may be generated, and thus, the number of plurality of intervals may be reduced and also be reduced to half (i.e., half of the number) of the variable end-effectors. That is, the number of plurality of intervals for measuring the amount of light received by the light receiving part may be minimized.

For example, the end-effector may be provided as five end-effectors, i.e., two variable end-effectors are disposed each of above and below the reference end-effector with respect to the reference end-effector, and the amount of light received by the light receiving part may be measured at four intervals. Only the light irradiated from the first light source may be covered by the reference end-effector in the normal state at a maximum interval (or initial interval) of the plurality of end-effectors, and the amount of light received by the light receiving part at the maximum interval (e.g., the first interval) of the plurality of end-effectors may be measured firstly. Here, the light irradiated from the second light source(s) above the first light source may pass through the lower portion of each of the variable end-effectors above the reference end-effector and be received by the light receiving part. In addition, the light irradiated from the second light source(s) above the first light source may pass through the upper portion of each of the variable end-effectors below the reference end-effector and be received by the light receiving part.

In addition, while reducing the interval between the plurality of end-effectors, the light irradiated from the outermost second light source(s) in the normal state may be measured at the second interval at which the light received by the light receiving part is covered by the pair of variable end-effectors that are farthest (or outermost) from the reference end-effector. Here, the light irradiated from the second light source adjacent to the upper portion of the first light source may pass through the lower portion of the variable end-effector adjacent to the upper portion of the reference end-effector and be received by the light receiving part. In addition, the light irradiated from the second light source adjacent to the lower portion of the first light source may pass through the upper portion of the variable end-effector adjacent to the lower portion of the reference end-effector and be received by the light receiving part.

In addition, while (further) reducing the interval between the plurality of end-effectors, the amount of light received by the light receiving part may be measured at a third interval at which the light irradiated from the second light source(s) adjacent to the first light source in the normal state is covered by the pair of variable end-effectors adjacent to the reference end-effector. Here, the light irradiated from the first light source may be covered by the reference end-effector. In addition, the light irradiated from the second light source at the outermost portion above the first light source may pass through the upper portion of the upper outermost variable end-effector and be received by the light receiving part. Additionally, the light irradiated from the second light source at the outermost portion below the first light source may pass through the lower portion of the lower outermost variable end-effector and be received by the light receiving part.

In addition, the interval between the plurality of end-effectors may be reduced to a minimum interval (or critical interval) of the plurality of end-effectors, and only the light irradiated from the first light source may be covered by the reference end-effector in the normal state at the minimum interval of the plurality of end-effectors, and also, the amount of light received by the light receiving part may be measured fourthly at the minimum interval (for example, the fourth interval) of the plurality of end-effectors. Here, the light irradiated from the second light source(s) above the first light source may pass through the upper portion of each of the variable end-effectors above the reference end-effector and be received by the light receiving part. In addition, the light irradiated from the second light source(s) above the first light source may pass through the lower portion of each of the variable end-effectors below the reference end-effector and be received by the light receiving part.

As described above, in the present inventive concept, the substrate transfer device according to the embodiment of the present inventive concept may detect the abnormality of the plurality of end-effectors through the abnormality detection unit to identify the abnormality of the end-effectors before transferring the substrate, thereby preventing the damage of the substrate and/or the throwing down of the substrate boat due to the defective transfer of the end-effectors from occurring in advance. Here, the abnormality detection unit may include the light emitting part and the light receiving part, and the light emitting part may include the plurality of light sources provided in numbers corresponding to the plurality of end-effectors to effectively detect the sagging of each of the plurality of end-effectors. In addition, the plurality of light sources may include the first light source corresponding to the reference end-effector and the second light source provided at the position different from that of the first light source, and the first light source and the second light source may be fixed at the positions different from each other. In this case, the first light source may irradiate the light to the reference end-effector in the normal state and adjust the distance between the plurality of end-effectors through the distance adjustment unit, and thus, even when the distance between the plurality of end-effectors is adjusted through the distance adjustment unit, the abnormality of the plurality of end-effectors may be detected without moving the positions of the plurality of light sources.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

1. A substrate transfer device comprising:
a plurality of end-effectors extending in a first direction and disposed in multi-stages in a second direction crossing the first direction to support substrates, respectively;
an interval adjustment unit configured to adjust an interval between the plurality of end-effectors; and
an abnormality detection unit configured to detect an abnormality of each of the plurality of end-effectors,
wherein the plurality of end-effectors comprise:
a reference end-effector that is fixed in position; and
a variable end-effector that is adjusted in distance from the reference end-effector with respect to the reference end-effector.

2. The substrate transfer device of claim 1, wherein the abnormality detection unit comprises a light emitting part and a light receiving part,
wherein the light emitting part comprises a plurality of light sources provided in numbers corresponding to the number of plurality of end-effectors.

3. The substrate transfer device of claim 2, wherein the plurality of light sources are fixed at positions different from each other in the second direction.

4. The substrate transfer device of claim 2, wherein the plurality of light sources comprise:
a first light source corresponding to the reference end-effector; and
a second light source provided at a position different from that of the first light source in the second direction.

5. The substrate transfer device of claim 4, wherein the second light source is provided in plurality, and
a distance between the first light source and the second light source, which are adjacent to each other, is different from a distance between the second light sources that are adjacent to each other.

6. The substrate transfer device of claim 5, wherein the distance between the first light source and the second light source, which are adjacent to each other, is greater than or equal to a minimum interval between the plurality of end-effectors and is less than the distance between the second light sources that are adjacent to each other.

7. The substrate transfer device of claim 2, wherein the abnormality detection unit comprises:
a light amount measurement part configured to measure an amount of light received by the light receiving part; and
an abnormality determination part configured to determine an abnormality of each of the plurality of end-effectors through the measured light amount.

8. The substrate transfer device of claim 7, wherein the abnormality detection unit further comprises a determination criterion storage part configured to store the amount of light received by the light receiving part according to the interval between plurality of end-effectors.

9. The substrate transfer device of claim 1, wherein the variable end-effector is provided in plurality, and
the plurality of variable end-effectors are disposed symmetrically with respect to the reference end-effector.

10. A method for determining an abnormality of a substrate transfer device, the method comprising:
storing an amount of light received to a light receiving part of an abnormality detection unit from a light emitting part of the abnormality detection unit for each interval of a plurality of end-effectors, while adjusting the interval between the plurality of end-effectors comprising a reference end-effector and a variable end-effector;
first measuring an amount of light received by the light receiving part in a state in which the interval between the plurality of end-effectors is set to a first interval;
comparing the stored amount of light at the first interval with the amount of light measured in the first measuring;
second measuring the amount of light received by the light receiving part in a state in which the interval between the plurality of end-effectors is set to a second interval different from the first interval; and
comparing the stored amount of light at the second interval with the amount of light measured in the second measuring.

11. The method of claim 10, wherein the stored amount of light at the second interval is different from the stored amount of light at the first interval.

12. The method of claim 10, wherein the second measuring is performed when a difference between the stored amount of light at the first interval and the amount of light measured in the first measuring is within an allowable error range.

13. The method of claim 10, further comprising additionally measuring the amount of light received by the light receiving part in a state in which the interval between the plurality of end-effectors is set to an interval other than the first interval and the second interval so as to be compared with the stored amount of light at the interval other than the first and second intervals.

14. The method of claim 10, wherein the light emitting part comprises a plurality of light sources provided in numbers corresponding to the number of plurality of end-effectors, and
the first interval and the second interval are determined depending on positions of the plurality of light sources.

15. The method of claim 14, wherein light irradiated from a first light source corresponding to the reference end-effector among the plurality of light sources is at least partially blocked by the reference end-effector in a normal state.

16. The method of claim 15, wherein the plurality of light sources further comprise a second light source provided at a position different from that of the first light source, and
one or less variable end-effectors are disposed between the first light source and the second light source, which are adjacent to each other.

17. The method of claim 14, wherein an interval between the plurality of end-effectors is adjusted by driving a motor, and
the method further comprises storing motor encoder (motor encoder) values of the first interval and the second interval.

18. The method of claim 10, wherein the variable end-effector is provided in plurality, and
the plurality of variable end-effectors are disposed symmetrically with respect to the reference end-effector.
